(19) United States
(12) Patent Application Publication
(10) Pub. No.: US 2021/0094823 A1
(43) Pub. Date: Apr. 1, 2021

(54) HUMIDITY REDUCTION DEVICE FOR OZONE PRODUCTION

(71) Applicant: MicroPlasma Ozone Technologies, Inc., Champaign, IL (US)

(72) Inventors: Michael A. Kistler, Champaign, IL (US); Cassie Leigh, Champaign, IL (US); Luis Chung, Savoy, IL (US); Elizabeth C. Hamil, San Luis Obispo, CA (US); Cyrus M. Herring, Tolono, IL (US)

(73) Assignee: MicroPlasma Ozone Technologies, Inc., Champaign, IL (US)

(21) Appl. No.: 17/034,441

(22) Filed: Sep. 28, 2020

Related U.S. Application Data
(60) Provisional application No. 62/906,439, filed on Sep. 26, 2019.

(51) Int. Cl. C01B 13/10; H01L 35/30

(52) U.S. Cl. CPC C01B 13/10; H01L 35/30

(57) ABSTRACT

A solid-state electronic dehumidifier (SSED) to improve the performance, productivity and longevity of small-scale ozone-generating devices. By removing moisture upstream of the ozone generator, the SSED stabilizes the ozone generator's rated ozone output. Reducing moisture content in the process gas (air), increases unit performance, and the lifetime of the ozone-generating cell is increased by reducing nitric acid generation. The system includes an SSED upstream from an ozone generator. The SSED has an outer housing divided into two chambers, a cold side and a hot side, by a dividing panel. The SSED has a cold heat sink located in the cold side and a hot heat sink located in the hot side, with a heat exchange unit secured in the dividing panel in contact with both cold and hot heat sinks. Air flow through the hot and cold sides dehumidifies the air in the cold side and is directed to the ozone generator.

### RELATED APPLICATIONS

The present application claims priority under 35 U.S.C. § 119 to U.S. Provisional Application No. 62/906,439, filed Sep. 26, 2019, the contents of which are expressly incorporated herein.

### FIELD OF THE INVENTION

The present invention is directed to a device for humidity reduction as a precursor to small-scale ozone generation.

### BACKGROUND OF THE INVENTION

Ozone (O₃) is a gas derived from oxygen which can be readily dissolved in water, where it is referred to as Aqueous Ozone (which has no odor or color). Ozone is an EPA approved antimicrobial oxidizer, sanitizer and disinfectant, and Aqueous Ozone is an effective micro-flocculent and effective anti-foaming agent. Indeed, the disinfecting capability of 1 PPM Aqueous Ozone is equivalent to many times (10 to 15,000 times) the concentration of free available chlorine, depending on pH, temperature, and on the specific microorganisms to be destroyed. Ozone is produced by an ozone generator at the point of use (utilizing only air and electricity) and converts back to oxygen leaving no harmful byproducts making it both a green and sustainable technology. Ozone is an approved organic food additive under the USDA National Organic Program. Ozone is an EPA Approved Antimicrobial, Disinfectant & Sanitizer by definition and ozone performs these functions as an oxidizer.

Ozone Generators have been in use in residential pools since the early 1980s. In the early days, the systems had a wide size range of ozone outputs, but as the popularity evolved, they became relatively small. Today, the most common ozone systems create between 0.2-0.5 grams of ozone per hour (some even less). Although some ozone is better than no ozone, these systems do not provide enough ozone to be as effective as they could or should be. Ozone reduces the use of chlorine and ancillary chemical additives dramatically which offers a healthy swimming environment and beautiful pools.

Ozone gas can be produced by passing air (or oxygen) through a light energy field or electrical energy field in a chamber. Generally, there are three types of ozone generators or ozonators that are used in spa and swimming pool disinfection. 1) Corona Discharge Generators, 2) Ultra-Violet Light Generators, and 3) Plasma or MicroPlasma Generators.

CD (Corona Discharge) Ozone is ozone produced with electrical energy (high voltage/low amperage). The quantity and concentration are substantially higher, and the energy cost is much lower than UV Ozone. In the CD ozone generator machines, air is exposed to multiple high voltage charges. The air in the system contains 20% oxygen and 80% nitrogen. The corona discharge ozonator systems are very cost effective and do not require an oxygen source, other than the ambient air. Unfortunately, when these types of ozonators are used, they produce nitrogen oxides as a by-product. To reduce or eliminate the formation of nitric acid, a desiccant air dryer is used to remove water (moisture) vapor from the air. Instead of an air dryer, an oxygen concentrator may be used to further increase ozone production and at the same time, reduce the risk of nitric acid formation by removing both moisture and the bulk of the nitrogen from the air. Nitrogen, typically in the form of nitric acid, reduces ozone production and creates corrosion and clogging of ozonators.

UV (Ultraviolet) Ozone is ozone produced with light energy (˜185 nm wavelength); the quantity and concentration are very limited, and the energy cost is high. However, UV ozone generating system work well in very high humidity air environments, and may be less expensive as they may not require any off gas mechanisms, desiccant air dryer systems or oxygen concentrators.

Plasma or Microplasma Ozone is the next generation in ozone production. Plasma produces a “uniform glow discharge,” as opposed to Corona Discharge, which is a “random discharge,” making more ozone with less energy, in similar sized units. In so-called “cold” plasma ozone generators pure oxygen is exposed to a plasma that is created by a dielectric barrier discharge, and the diatomic oxygen is split into single atoms. A cold plasma ozone generation system produces a far greater quantity of ozone in a given time period than a UV generator would, but is very expensive. Cold plasma ozone generators utilize pure oxygen as the input source and produce an ozone concentration of about 5%. Microplasma Ozone systems utilize a micro-channel ozone process, and have the potential for high conversion rates of air to ozone. The input can be ambient air, though nitrogen oxides are often produced requiring periodic maintenance.

Since roughly 2012, many Advanced Oxidation Processes “AOP” Systems have flooded the market for pool sanitizers. AOPs in a broad sense, are a set of chemical treatment procedures designed to remove organic (and sometimes inorganic) materials in water and wastewater by oxidation through reactions with hydroxyl radicals (.OH). The term AOP usually refers more specifically to a subset of such chemical processes that employ ozone (O₃), hydrogen peroxide (H₂O₂) and/or UV light. In an effort to offer the industry something different, some companies have combined small ozone generators with small UV sterilizers and call them AOP. Based on these ozone generator and UV outputs, again, so-called AOP production rates are insignificant and do not offer a quantifiable benefit for residential pools.

There remains a need for a more efficient and productive system for ozone generation for small-scale applications such as swimming pools, commercial aquariums and food preparation facilities where ozone is used as a disinfectant.

### SUMMARY OF THE INVENTION

It is an object of the present invention to improve performance of ozone generators by dehumidifying only the air that enters the ozone-generating cell, for air-fed ozone generators. The system includes a solid-state electronic dehumidifier (SSED) upstream from an ozone generator that removes moisture from ambient air to maintain rated ozone output performance. The SSED uses the process of condensation with a Peltier heat exchanger to remove water from ambient air. In order to condense the water out of ambient air it needs to come in contact with a surface that has a temperature below the dewpoint. While the dewpoint varies based on humidity, temperature, and atmospheric pressure, it is always lower than or equal to the ambient air temperature. By removing moisture upstream of the ozone generator, the SSED stabilizes the ozone generator's rated ozone output. Reducing moisture content in the process gas (air), increases unit performance, and the lifetime of the ozone-generating cell is increased by reducing nitric acid generation.

The advantageous use of the SSED directly feeding dehumidified air to an ozonator enables higher ozone output with less nitric acid generation, and thus less frequent need for servicing the ozonator. Moreover, the particular design of the SSED allows the components to be relatively small and inexpensive, which leads to greater availability for the average residential pool owner. Larger systems may be scaled up for public pools, of course.

A further understanding of the nature and advantages of the invention will become apparent by reference to the remaining portions of the specification and drawings.

### BRIEF DESCRIPTION OF THE DRAWINGS

Features and advantages of the present invention will become appreciated as the same become better understood with reference to the specification, claims, and appended drawings.

FIG. 1 is a diagrammatic view of a solid-state electronic dehumidifier (SSED) and ozone-generating system of the present application.

FIGS. 2A and 2B are bottom and side perspective views of an exemplary SSED used in the system of FIG. 1;

FIG. 3 is an exploded perspective view of the exemplary SSED;

FIG. 4 is an exploded perspective view of several internal heat exchange components of the SSED;

FIG. 5 is a perspective view of the internal heat exchange components assembled;

and

FIG. 6 is a schematic representation of an ozone generating system as described herein adjacent a residential pool.

### DETAILED DESCRIPTION OF THE PREFERRED EMBODIMENTS

The present application is directed to a system for generating ozone which is more efficient and productive for small-scale ozone generators.

Overview

Gaseous ozone production (ozone production in the gas phase as opposed to forming ozone in the liquid phase) for various residential and commercial applications is an on-demand and on-site process since the ozone gas naturally decomposes over minutes to hours depending on the temperature and constituents of the gas. The efficiency and concentration of ozone gas produced by ozone generators depends on the quality of starting gas which is typically ambient air or oxygen and is typically in the 0.01% to 10% ozone by weight. For low-cost applications ambient air is the preferred starting gas since the oxygen source or generator can add significant costs to the ozone system. For gas ozone generators that use air for generating ozone, the humidity of the air influences ozone generation efficiency, ozone concentration, and also typically affects the longevity of the ozone generator. In general, higher ambient humidity results in reduced ozone output, lower ozone concentration, and shorter product lifespan. Therefore, it is important to have cost effective ways to reduce the humidity of ambient air before it enters the ozone generator.

Having the air cooler than ambient will also help ozone production as this is dependent on temperature. In general, gaseous ozone generators are more efficient and produce a higher concentration of ozone as the temperature of the air is reduced.

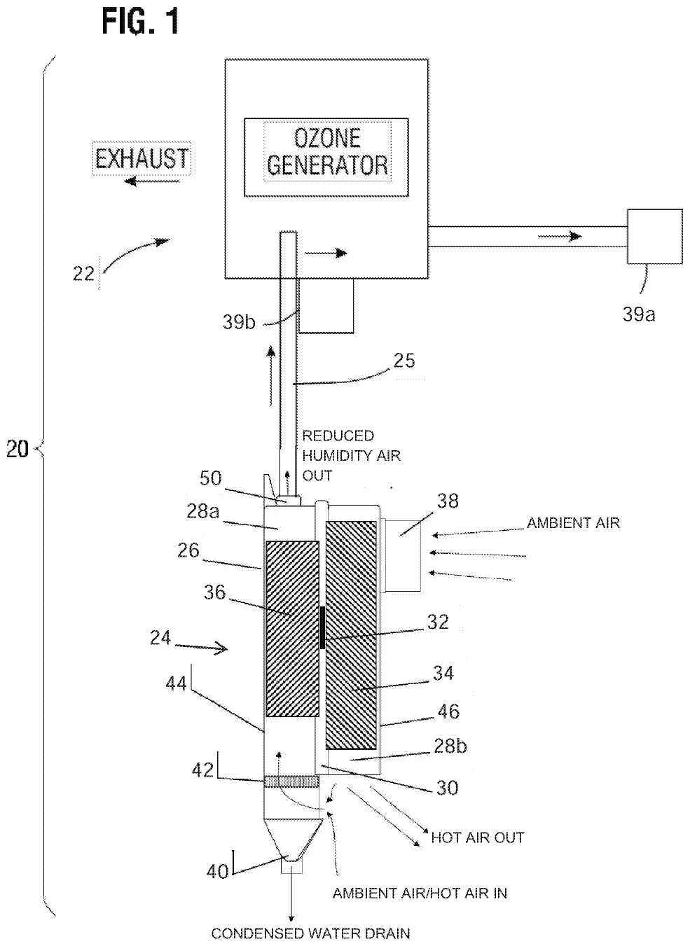

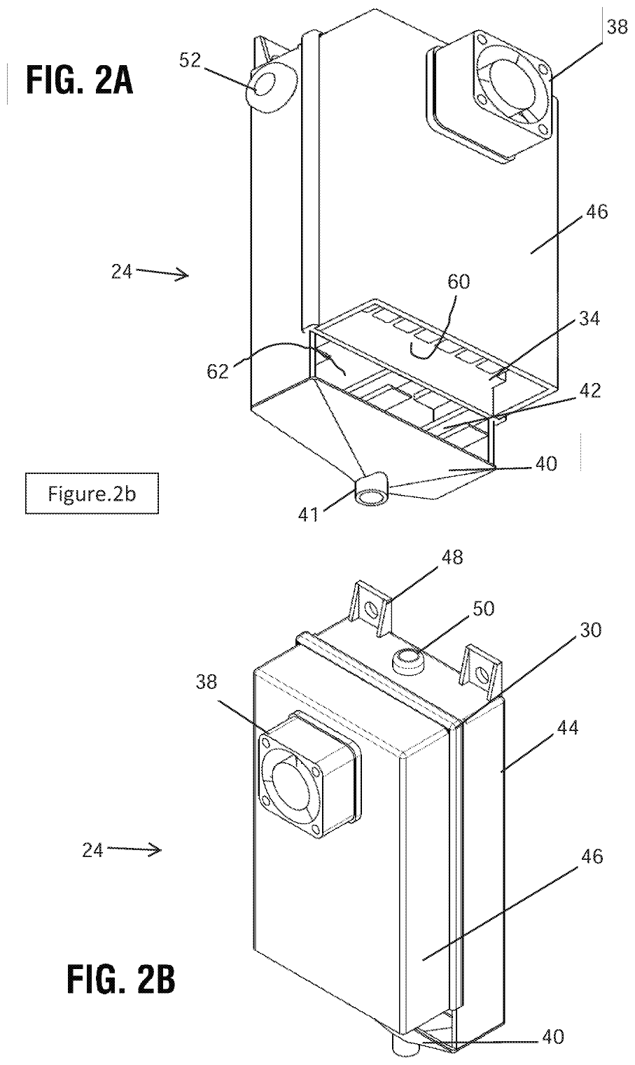

FIG. 1 schematically illustrates a solid-state electronic dehumidifier (SSED) and ozone-generating system 20 of the present application. The system comprises an ozone generator 22 and a solid-state electronic dehumidifier (SSED) 24 connected via a conduit 25. The SSED 24 is seen in greater detail in FIGS. 2-5, and generally includes an outer housing 26 which may be rectilinear (rectangular and boxy) as shown. The outer housing is comprised of 4 parts: cold side housing 44, collection cup 40, divider plate 30, and hot side housing 46. The ozone generator 22 may be a variety of types as described above, including an UV (Ultraviolet) Ozone generator, a CD (Corona Discharge) generator, or a Microplasma Ozone generator. One particularly useful ozone generator 22 is an MP5 (Air) Smart Ozone System produced by MicroPlasma Ozone Technologies, Inc. The MP5 (Air) Smart Ozone System is rated for at least 2 grams of ozone per hour, easily enough for most residential pools.

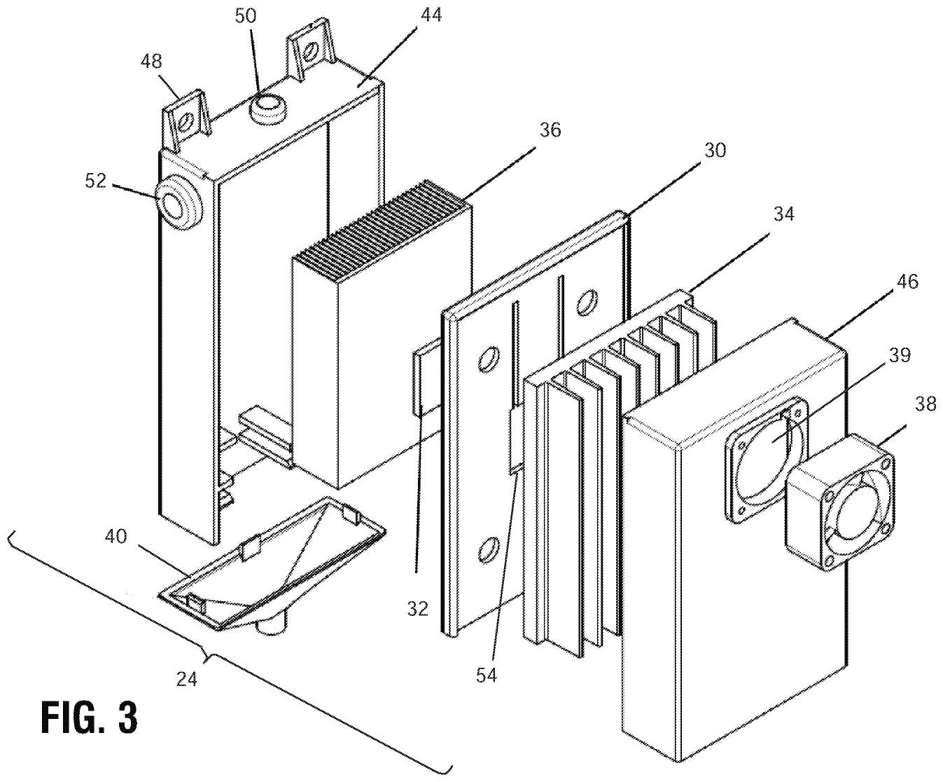

The SSED 24 is bifurcated into two internal vertically-oriented chambers—a cold side chamber 28a and a hot side chamber 28b by a vertical central wall or panel 30. A heat exchange unit 32, such as a Peltier Cooler, is secured in an aperture 54 (FIGS. 3 & 4) in the central panel 30 and in direct contact with a plurality of evaporation fins 34 on the hot side chamber 28b and a plurality of condensation fins 36 on the cold side chamber 28a. A fan 38 fastened to the outer housing 26 in communication via an upper inlet 39 of the hot side chamber 28b blows across the evaporation fins 34. There is no fan for pushing air through the hot side housing 46, only passive flow. It should be noted that though the SSED 24 is desirably vertically-oriented, for various reasons including facilitating removal of condensate from the lower collection cup 40, the components could be other than vertical with some plumbing adjustments.

In use, the hot side fan 38 pulls ambient air into the upper inlet 39 on the hot side chamber 28b. Because the hot side chamber 28b is closed at its upper end, the air is blow downward past the evaporation fins 34. At the lower end of the hot side chamber 28b, as best seen in FIG. 2A, the housing is open at a lower air outlet 60. In the illustrated embodiment, the lower air outlet 60 is simply a missing lower wall of the rectangular hot side housing 46, though a more channeled air flow may include side walls and/or deflectors. The housing 44 of the cold side chamber 28a extends downward below the lower air outlet 60 and is open on the side facing the hot side housing 46 to form a lower air opening 62. The upper edge of the lower air opening 62 is coincident with an inside lower edge of the lower air outlet 60 so that some of the air flowing downward though the hot side chamber 28b flows into the cold side chamber 28a, as indicated by the flow arrows in FIG. 1.

Different systems may move air through the conduit 25, upper exit port 50, cold side chamber 28a, and a particulate filter 42 such that the general direction of air flow is shown by the flow arrows in FIG. 1. For aqueous ozone applications, a venturi injector or device 56a downstream from the ozone generator 22 creates a negative pressure that pulls the ozone into the water and dissolves it to produce Aqueous Ozone. The flow of ozone through the ozone generator 22 creates a flow over the mouth of the inlet of the conduit 25, which in turn pulls air through the conduit from the SSED 24, by virtue of a venturi effect. Alternatively, for gaseous ozone applications, an air pump or device 56b is located after the SSED 24 and before the ozone-generating cell(s) in the generator 22. In either case, air flows into the wide lower air opening 62 (FIG. 2A) of the cold side chamber 28a, drawn both from the lower air outlet 60 of the hot side chamber 28b and from the surrounding ambient air, and flows upward through the cold side chamber 28a past the condensation fins 36.

The Peltier Cooler heat exchange unit 32 is a solid-state active heat pump which transfers heat from the cold side chamber 28a of the device 24 to the hot side chamber 28b. The heat exchange unit 32 usually has a flat form factor and is enabled by supplying a DC voltage and current (not shown). When operating, one side of the heat exchange unit 32 becomes hot and the other side becomes cold. When the hot side chamber 28b of a heat exchange unit 32 is maintained above ambient temperature then the cold side chamber 28a will become colder than ambient temperature. The difference in temperature from the hot side to cold side is based on the Peltier Cooler's specific characteristics and the rate that heat is added to or taken away from its surfaces. The Peltier Cooler is desirably compressed between the condenser sink 36 and the hot heat sink 34. A layer of thermally conductive material 33 can be installed between the Peltier Cooler 32 and each heat sink 34, 36 to aid in thermal conductivity, and an insulation layer 35 (incorporated in the wall 30) can be placed between the hot and cold heat sinks to improve efficiency.

Consequently, the evaporation fins 34 heat up above ambient and the condensation fins 36 cool down below ambient. This causes moisture to condense on the condensation fins 36 and drain down into the collection cup 40 which dehumidifies the air passing through the conduit 25 to the ozone generator 22. Preferably, the collection cup 40 is shaped like a shallow funnel to channel the condensate to a single outlet nozzle 41.

In an alternative embodiment, a second cold chamber 28a is stacked next to the first cold side to provide a second evaporation/dehumidifying step. Although not shown, this may be desirable to enhance the efficiency of the entire system without having to include a much larger cold sink.

The SSED 24 treats air at a rate of 1 to 50 liters per minute. In one embodiment, the housing 26 is roughly 5 inches long (tall) by 4¼ inches wide on the exterior and can process air flow of about 10 liters per minute (LPM). More generally, small-scale dehumidifiers as described herein are preferably between 4-8 inches long (tall) by 3-6 inches wide, and have a depth of between 2-4 inches. Such an SSED 24 is suitable for connection to an ozone generator 22 which produces a minimum of 2 grams of ozone per hour (GPH). The disclosed SSED 24 is configured to produce 1 to 50 LPM of cool dry air. The SSED 24 limits the relative humidity in the process air to below 50%, and more preferably to between 20-30%.

Advantageously, the disclosed SSED 24 produces an air flow rate of about 11 LPM into an ozone generator 22 such as the MP5 (Air) Smart Ozone System to generate about 2 GPH of ozone, sufficient for a residential pool. Scaling up to an air flow rate of 50 LPM would enable ozone production of about 10 GPH, enough for larger public pools, for example. Systems requiring larger amounts of ozone, such as those for industrial processing, require concentrated oxygen as an input for the ozone generator.

One beneficial attribute is being able to remove water without freezing it which can cause a decrease in air flow as ice can impede the air flow path. The SSED 24 cold side chamber 28a allows for entry of ambient air, followed by cooling of the air with the surface of the cold heat sink 36, which then flows through a sealed passage through the condenser to the ozone generator 22. As the air cools below the dew point, water droplets form on the heat sink, drain down into the collection cup 40 and reduce the humidity of the treated air.

The cold chamber 28a is sealed or isolated on one end with just the exit port 50 leading to the conduit 25 where the dehumidified air is plumbed into the ozone generator 22. The housing 26 has a very specific size to make sure that the air flow is slow enough to allow adequate time for the water to condense out of the air. The condenser sink 36 is sized to the chamber 28a and has a specific length to allow the maximum contact with the incoming air. The Peltier Cooler heat exchange unit 32 was chosen to allow for a large enough temperature drop from the hot side to the cold side and is actively controlled with a microcontroller such that it will not freeze the water on the condenser. The hot side heat sink was chosen to ensure adequate heat removal. Under the influence of gravity, the condensed water is then captured by a portion of the housing at the lowest spot (collection cup 40) to allow for disposal. The small fan 38 is preferably attached to the hot side chamber housing 46 to assist with heat removal.

One reason for the efficient functioning of the SSED 24 without freezing of air is that the fan 38 is only provided on the hot side chamber 28b, in conjunction with a passive flow upward across the cold side chamber 28a. Prior dehumidifiers utilize fans on both hot and cold sides.

Although cooling and condensation of water drops the moisture content of the air, it still remains at high relative humidity. The cooled air must be re-heated to drop the relative humidity to provide a benefit to the ozone generator. This can be achieved by using heat from the hot side of the Peltier cooler or allowed to warm through a length of tubing, or by adding an electric heater. This will ensure the air entering the ozone generator will have lower relative humidity.

In order to improve efficiency of the device, the condensed water from the condenser can be transported to the hot side to aid in evaporative cooling of the hot side of the heat pump. In this embodiment the cool side can be placed above the hot side and the condensed water can be gravity fed to the hot side of the device which would be below the cool side.

In another modification, the conduit 25 leading to the ozone generator 22 may be warmed by the Peltier element 32. For instance, the conduit 25 may be detoured back into the hot side chamber 28b and past the Peltier element 32 before continuing on to the ozone generator 22.

SSED

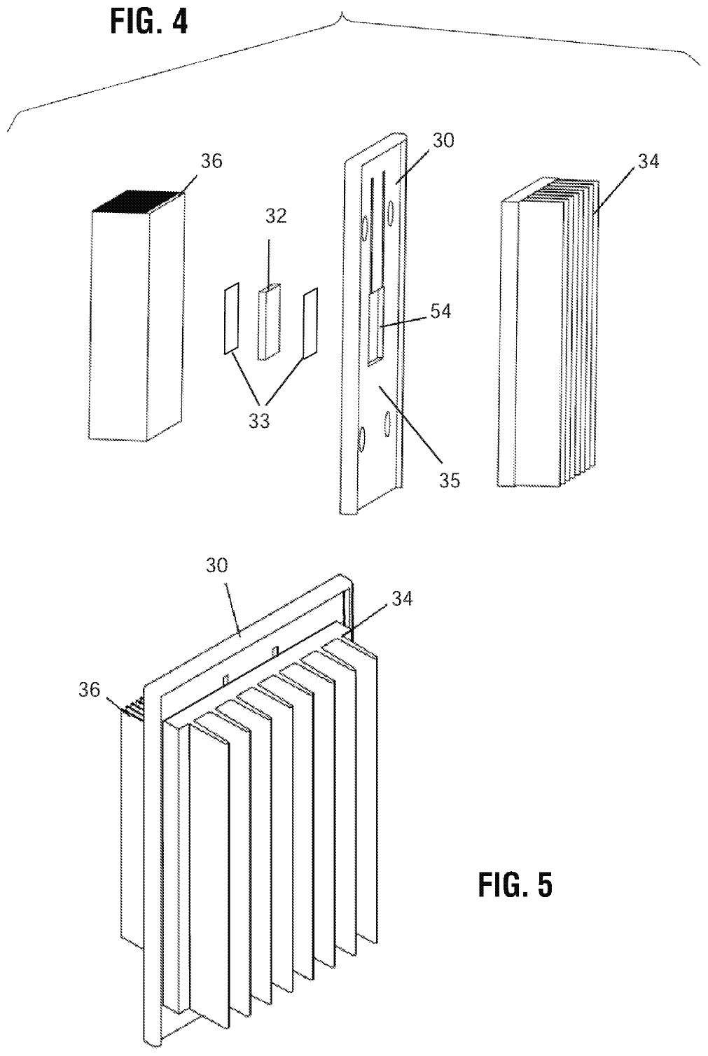

FIGS. 2A and 2B show bottom and side perspective views of the SSED 24, while the exploded views of FIGS. 3 and 4 illustrate further internal details. In one embodiment, the housing 26 is made by attaching plastic U-channel pieces 40 and plastic flat stock together to form a square chamber with the dividing wall 30 separating the cold and hot sides 28a, 28b. The heat exchange unit 32 fits closely within a rectangular aperture 54 through the dividing wall 30 and is in direct contact with both the hot and cold heat sinks 34, 36. In one embodiment, the housing 26 is made up of 4 main parts. The cold side housing 44, contains the condensing sink 40. The housing also has specific openings to allow power connections 52, gas flow out through exit port 50, and further includes mounting points or brackets 48. The cold side housing also contains the filter holders and filter 42. The particulate filter catches any dust or dirt going into the SSED 24 cold side housing 44 from the outside air.

The collection cup 40 mounts to the bottom of the cold side housing. A line 49 can be connected to the collection cup 40 which allows for condensed water to drain from the device.

The divider plate 30 separates the hot chamber 28b and cold chamber 28a and has a rectangular cut out 54 in which the Peltier Cooler heat exchange unit 32 closely fits and makes direct contact with the condenser sink 36 and evaporative sink 34. The hot side housing 46 contains the evaporative sink 34 and has the mounts for the fan 38. Also, housings are sealed together to form airtight chambers.

As seen in FIG. 1, the cold and hot sides 28a, 28b of the SSED 24 are preferably open at their bottom ends so as to freely drain any condensed liquid. Aside from the open bottoms, the cold chamber 28a is sealed or isolated to prevent any humid air from entering the area in which air has been dehumidified. This ensures a particular level of humidity entering the conduit 25 to the ozone generator 22.

Electronic monitoring of ambient air temperature, humidity, and pressure as well as monitoring of the cold-side temperature give information to an embedded microcontroller to control power to the device to prevent freeze-up under certain atmospheric conditions.

The SSED 24 can be a stand-alone unit to dehumidify air going into the ozone generator 22, or incorporated into the ozone generator and sold as a single system.

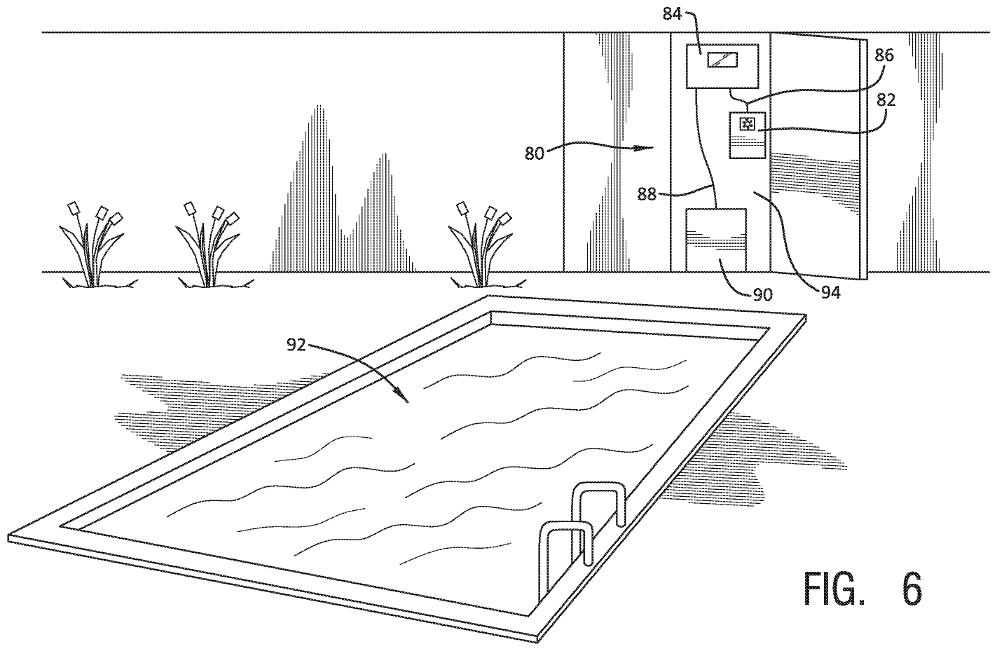

FIG. 6 is a schematic representation of an ozone generating system 80 as described herein adjacent a residential pool. The system 80 includes a solid-state electronic dehumidifier (SSED) 82 connected upstream of an ozone generator 84. The SSED 82 is as described elsewhere herein, and includes an outlet line 86 that leads directly into an input to the ozone generator 84. The ozone generator 84, in turn, has an outlet line 88 leading to a water/gas mixing and pumping system 90 that supplies dissolved ozone in water to an adjacent pool 92.

The system 80 is shown mounted within a shed or enclosure 94 next to the pool 92. The small size of the components 82, 84 facilitates placement of the system 80 in close proximity to the other pool system components, and lends itself to widespread acceptance in the market. No special mounting considerations apply, and since the SSED 82 dehumidifies ambient air, no additional components such as oxygen generators or air dryers are required, thus reducing costs. Moreover, feeding the dehumidified air directly into the ozone generator 84 greatly improves efficiency and reduces detrimental formation of nitric acid in the generator, which in turn reduces maintenance needs over the long term.

Both the SSED 82 and ozone generator 84 are sealed in a robust fashion so as to be rated for outdoor use. To date there are no outdoor dehumidifiers for residential pool use that are rated for outdoor placement, and certainly no small-scale outdoor dehumidifiers such as the disclosed SSED 24. Various regulatory agencies such as the National Electrical Code (NEC) and National Electrical Manufacturer Association (NEMA) promulgate standard rating systems that define the types of environments in which an electrical enclosure can be used, and frequently signifies a fixed enclosure's ability to withstand certain environmental conditions. The SSED 82 and ozone generator 84 both meet various such standards as defined in the U.S. and abroad, which will be collectively known as being “exterior rated.”

### CONCLUSION

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, if present, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

Those skilled in the art will appreciate that various changes and modifications may be made to the preferred embodiments, the invention in its broader aspects is not limited to the specific details, representative devices, and illustrative examples shown and described.

It is claimed:

1. An exterior rated ozone generating system, comprising:
an exterior rated ozone generator having an air inlet port and an external conduit connected thereto;
an exterior rated solid-state electronic dehumidifier (SSED) having an air flow capacity of between 1 and 50 LPM, the SSED including:
a housing divided by a central wall into a hot chamber and a cold chamber;
the hot chamber having an upper air inlet with a powered inlet fan for drawing ambient air into the hot chamber and a lower air outlet, and a hot chamber heat sink between the air inlet and air outlet;
the cold chamber having a lower air opening positioned adjacent the lower air outlet of the hot chamber and an upper air outlet, and a cold chamber heat sink between the lower air opening and upper air outlet; and
a powered Peltier element mounted in the central wall with a cold side attached to the cold chamber heat sink and a hot side attached to the hot chamber heat sink;
wherein the upper air outlet of the cold chamber is connected by the external conduit so as to direct dehumidified air that flows through the SSED to the inlet port of the ozone generator, wherein the dehumidified air that passes through the conduit is warmed by outside air prior to reaching the ozone generator.

2. The device of claim 1, wherein the cold chamber has a lower collector to allow condensed water to drain from the chamber.

3. The device of claim 1, wherein the ozone generator is a microplasma ozone generator capable of generating at least 2 GPH of ozone with an input air flow of about 11 LPM.

4. The device of claim 1, wherein there is no air flow fan mounted at the lower air opening or the upper air outlet of the cold chamber.

5. The device of claim 1, wherein the SSED housing is about 4-8 inches tall by 3-6 inches wide.

6. The device of claim 1, wherein the housing has a vertical height and a lateral width, and the lower air outlet of the hot chamber is formed by a missing lower wall in the housing so that the lower air outlet has the same width as the housing.

7. The device of claim 6, wherein the lower air opening of the cold chamber has the same width as the housing and is adjacent to the lower air outlet of the hot chamber.

8. The device of claim 7, wherein a first portion of the housing defining the cold chamber extends downward below a second portion of the housing defining the hot chamber, and the lower air opening is formed by an open wall of the first portion of the housing having an upper edge coincident with an edge of the lower air outlet.

9. The device of claim 1, further including a particulate filter provided in a lower portion of the cold chamber above the lower air opening.

10. The device of claim 1, further including a layer of thermally conductive material positioned between the Peltier element and each of the hot and cold chamber heat sinks, and an insulation layer placed between the hot and cold heat sinks to improve efficiency.

11. A system for supplying dehumidified air to an ozone generator, comprising:
a housing divided by a vertical wall into a vertically-oriented hot chamber and a vertically-oriented cold chamber, wherein the housing has a vertical height and a lateral width,
the hot chamber having an upper air inlet with a powered inlet fan for drawing ambient air into the hot chamber and a lower air outlet, and a hot chamber heat sink between the air inlet and air outlet, wherein the lower air outlet is formed by a missing lower wall in the housing so that the lower air outlet has the same width as the housing;
the cold chamber having a lower air opening positioned adjacent the lower air outlet of the hot chamber and an upper air outlet, and a cold chamber heat sink between the lower air opening and upper air outlet, wherein the lower air opening of the cold chamber has the same width as the housing and is adjacent to the lower air outlet of the hot chamber;
a powered Peltier element mounted in the vertical wall with a cold side attached to the cold chamber heat sink and a hot side attached to the hot chamber heat sink; and
a conduit on the cold side adapted to directly connect and supply dehumidified air to an ozone generator at a flow rate of between 1-50 LPM.

12. The device of claim 11, wherein the cold chamber has a lower collector to allow condensed water to drain from the chamber.

13. The device of claim 12, wherein the lower collector is a funnel-shaped collection cup formed by the housing at a lower end of the cold chamber.

14. The device of claim 11, wherein there is no air flow fan mounted at the lower air opening or the upper air outlet of the cold chamber.

15. The device of claim 11, wherein the housing is about 4-8 inches tall by 3-6 inches wide.

16. The device of claim 11, wherein a first portion of the housing defining the cold chamber extends downward below a second portion of the housing defining the hot chamber, and the lower air opening is formed by an open wall of the first portion of the housing having an upper edge coincident with an edge of the lower air outlet.

17. The device of claim 11, further including a particulate filter provided in a lower portion of the cold chamber above the lower air opening.

18. The device of claim 11, wherein the Peltier element is fixed within an aperture in the vertical wall.

19. The device of claim 11, further including a layer of thermally conductive material positioned between the Peltier element and each of the hot and cold chamber heat sinks.

20. The device of claim 19, further including an insulation layer placed between the hot and cold heat sinks to improve efficiency.
